(19) United States
(12) Patent Application Publication
(10) Pub. No.: US 2025/0006621 A1
(43) Pub. Date: Jan. 2, 2025

(54) ELECTRONIC DEVICE

(71) Applicant: Rohm Co., Ltd., Kyoto-shi (JP)

(72) Inventors: Ryohei UMENO, Kyoto-shi (JP); Hiroaki MATSUBARA, Kyoto-shi (JP); Tomohira KIKUCHI, Kyoto-shi (JP)

(21) Appl. No.: 18/883,587

(22) Filed: Sep. 12, 2024

Related U.S. Application Data
(63) Continuation of application No. PCT/JP2023/006238, filed on Feb. 21, 2023.

(30) Foreign Application Priority Data
Mar. 17, 2022 (JP) 2022-043110

(51) Int. Cl. H01L 23/498; H01L 23/00; H01L 23/29; H01L 23/31; H01L 25/065

(52) U.S. Cl. CPC H01L 23/49838; H01L 23/293; H01L 23/3121; H01L 23/49811; H01L 24/48; H01L 24/49; H01L 25/0655; H01L 2224/48138; H01L 2224/48175; H01L 2224/49051; H01L 2224/49173; H01L 2224/49431; H01L 2924/186

(57) ABSTRACT

An electronic device includes: an electronic component; a sealing resin covering the electronic component; a first lead including a first inner portion and a first outer portion; a second lead including a second inner portion and a second outer portion; and a wire including a bonding segment secured to the first inner portion and a bonding segment secured to the second inner portion. The first inner portion is located inside a peripheral edge of the sealing resin as viewed in a thickness direction z, except at a first boundary with the first outer portion. The second inner portion is located inside the peripheral edge of the sealing resin as viewed in the thickness direction z, except at a second boundary with the second outer portion. As viewed in the thickness direction z, the wire has a length that is at least 25% of an average of a distance from the first boundary to the bonding segment secured to the first inner portion and a distance from the second boundary to the bonding segment secured to the second inner portion.

### TECHNICAL FIELD

The present disclosure relates to electronic devices.

### BACKGROUND ART

As a type of electronic devices, semiconductor devices manufactured using lead frames are conventionally known. JP-A-2017-191895 discloses an example of such a semiconductor device. The semiconductor device disclosed in the document includes an island, a lead, a semiconductor chip, a wire, and a resin package. The semiconductor chip is mounted on the island. The lead is isolated from the island. The island and the lead are made from the same lead frame. The wire is bonded to the semiconductor chip and the lead. The resin package encapsulates the island, the lead, the semiconductor chip, and the wire together.

### BRIEF DESCRIPTION OF THE DRAWINGS

FIG. 1 is a plan view of an electronic device according to a first embodiment.

FIG. 2 is a plan view corresponding to FIG. 1, in which a sealing resin is indicated with an imaginary line.

FIG. 3 is an enlarged plan view showing a portion of FIG. 2.

FIG. 4 is an enlarged plan view showing a portion of FIG. 2.

FIG. 5 is a front view of the electronic device according to the first embodiment.

FIG. 6 is a rear view of the electronic device according to the first embodiment.

FIG. 7 is a left-side view of the electronic device according to the first embodiment.

FIG. 8 is a right-side view of the electronic device according to the first embodiment.

FIG. 9 is a sectional view taken along line IX-IX in FIG. 2.

FIG. 10 is a sectional view taken along line X-X in FIG. 2.

FIG. 11 is a circuit diagram of the electronic device according to the first embodiment.

FIG. 12 is a plan view of an electronic device according to a second embodiment, in which a sealing resin is indicated with an imaginary line.

FIG. 13 is an enlarged plan view showing a portion of FIG. 12.

FIG. 14 is an enlarged plan view showing a portion of FIG. 12.

FIG. 15 is a front view of the electronic device according to the second embodiment.

FIG. 16 is a rear view of the electronic device according to the second embodiment.

FIG. 17 is a plan view of an electronic device according to a variation of the second embodiment, in which a sealing resin is indicated with an imaginary line.

FIG. 18 is a plan view of an electronic device according to a third embodiment, in which a sealing resin is indicated with an imaginary line.

FIG. 19 is a circuit diagram of the electronic device according to the third embodiment.

FIG. 20 is a plan view of an electronic device according to a variation of the third embodiment, in which a sealing resin is indicated with an imaginary line.

### DETAILED DESCRIPTION OF EMBODIMENTS

With reference to the accompanying drawings, the following describes preferred embodiments of an electronic device according to the present disclosure. In the description, identical or similar elements are denoted by the same reference numerals, and overlapping explanations are omitted. In the present disclosure, the terms such as “first”, “second”, “third”, and so on are used only as labels and not to imply an order of the items referred to by the terms. The configurations of elements and components in the embodiments and variations described below may be combined in any manner, provided that no technical inconsistencies arise.

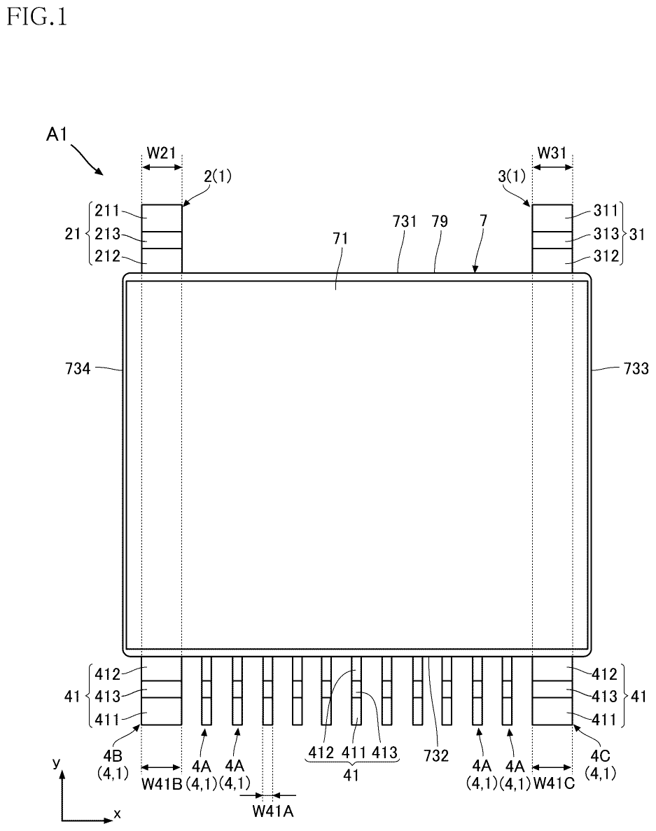

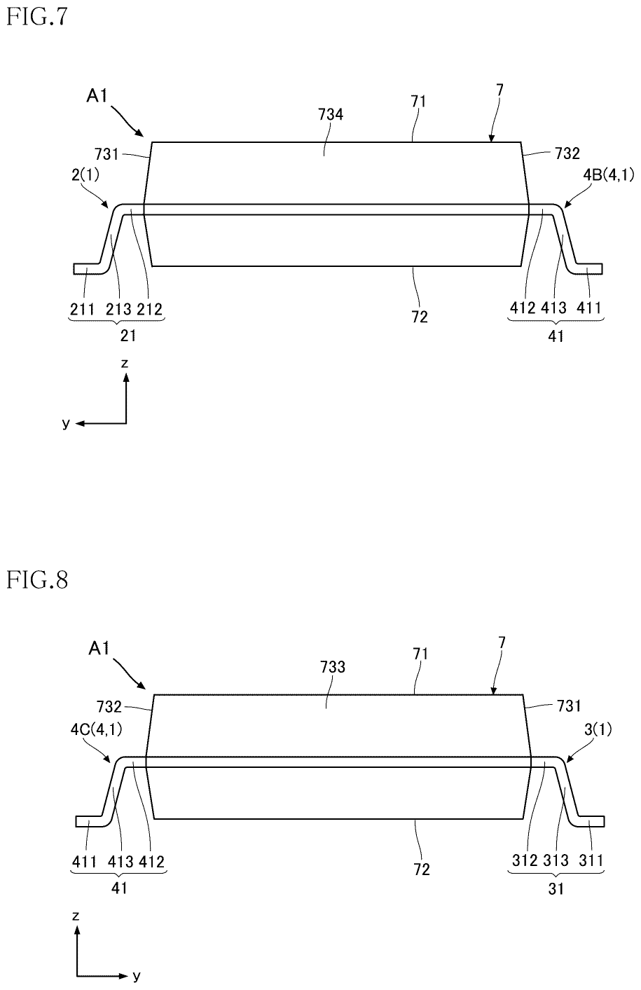

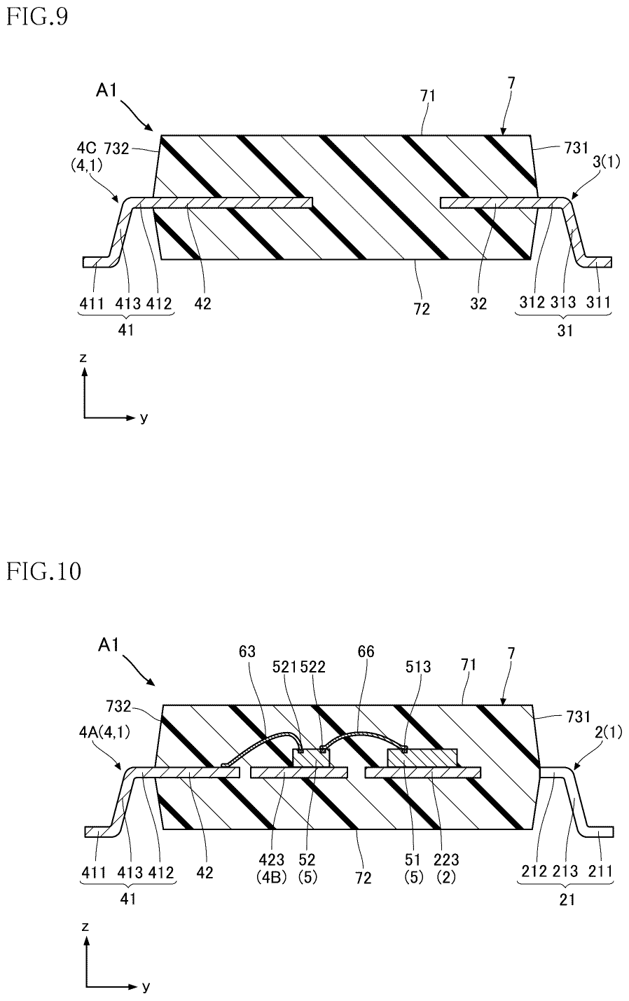

FIGS. 1 to 11 show an electronic device A1 according to a first embodiment. The electronic device A1 includes a plurality of leads 1, an electronic component 5, a plurality of wires 61 to 66, and a sealing resin 7. The electronic device A1 may be used in electric vehicles to detect battery voltage, for example. The electronic device A1 may also be used to detect voltages other than battery voltage in electric vehicles. Additionally, the electronic device A1 may be used to detect voltages in industrial equipment, home appliances, or power supplies other than electric vehicles. The electronic device A1 is a surface-mount semiconductor package, which in the present embodiment is a small outline package (SOP) as shown in FIGS. 1 to 10.

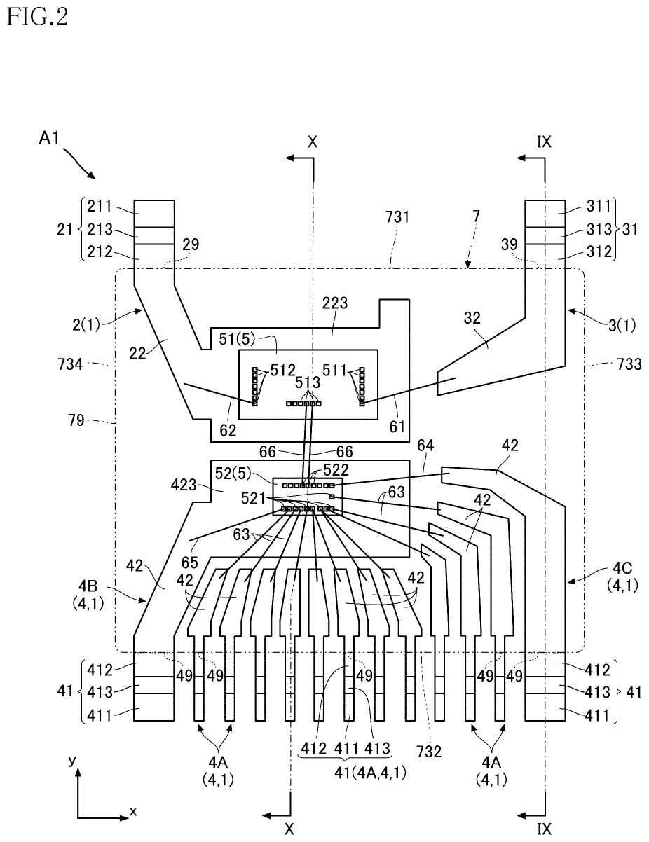

For the convenience of description, the thickness direction of the electronic device A1 is referred to as a “thickness direction z”. In the following description, a first side and a second side in the thickness direction z may be described as a location above or below. Note, however, that the terms such as “top”, “bottom”, “above”, “below”, “upper surface”, and “lower surface”, are used to describe the relative positions of elements, and not necessarily describe their positions with respect to the direction of gravity. In addition, “in plan view” refers to a view as seen in the thickness direction z. A direction orthogonal to the thickness direction z is referred to as a “first direction y”. The first direction y corresponds to a vertical direction in plan view of the electronic device A1 (see FIGS. 1 and 2). The direction orthogonal to the thickness direction z and the first direction y is referred to as a “second direction x”. The second direction x corresponds to a vertical direction in plan view of the electronic device A1 (see FIGS. 1 and 2).

The leads 1 is made of a material containing metal, such as copper (Cu), nickel (Ni), or iron (Fe). The plurality of leads 1 are formed from the same lead frame. The leads 1 are formed from a metal plate through a series of appropriate processes, including punching, bending, and etching. Portions of the leads 1 may be plated with, for example, silver (Ag), Ni or gold (Au) as necessary.

The plurality of leads 1 include a first lead 2, a second lead 3, and a plurality of third leads 4. Although the illustrated example shows 13 third leads 4, the number of third leads 4 is not specifically limited. The first to third leads 2, 3 and 4 are electrically connected to the electronic component 5 and form conduction paths of the electronic device A1. Note that one or more of the third leads 4 may not be electrically connected to the electronic component 5. The first to third leads 2, 3 and 4 are spaced apart from each other. Each of the first to third leads 2, 3 and 4 includes a portion covered with the sealing resin 7 and a portion exposed from the sealing resin 7.

The first lead 2 includes a first outer portion 21 and a first inner portion 22. The first outer portion 21 and the first inner portion 22 are connected to each other and formed as one piece.

The first outer portion 21 is the portion of the first lead 2 exposed from the sealing resin 7. The first outer portion 21 protrudes from the sealing resin 7 to a first side in the first direction y. In plan view, the first outer portion 21 is rectangular elongated in the first direction y. As viewed in the second direction x, the first outer portion 21 is bent into a gull-wing profile. The first outer portion 21 includes a first mounting section 211, a first root section 212, and a first intermediate section 213.

The first mounting section 211 is a terminal end of the first outer portion 21. For mounting the electronic device A1 on an electric vehicle, for example, the first mounting section 211 is bonded to the circuit board of the electric vehicle. As shown in FIGS. 1 and 2, the first mounting section 211 is the end of the first outer portion 21 away from the sealing resin 7 in the first direction y. Hence, the first mounting section 211 is located farther from the sealing resin 7 in the first direction y than the first root section 212 and the first intermediate section 213. In the thickness direction z, the first mounting section 211 is located below the first root section 212.

The first root section 212 is the starting end of the first outer portion 21. As shown in FIGS. 1 and 2, the first root section 212 is the end of the first outer portion 21 closer to the sealing resin 7 in the first direction y. Hence, the first root section 212 is located closer to the sealing resin 7 in the first direction y than the first mounting section 211 and the first intermediate section 213. The first root section 212 is located above the first mounting section 211 in the thickness direction z, and protrudes from the middle portion of the sealing resin 7 in the thickness direction.

The first intermediate section 213 connects the first mounting section 211 and the first root section 212. As viewed in the second direction x, the first intermediate section 213 is inclined relative to the first mounting section 211 and the first root section 212.

The first inner portion 22 is the portion of the first lead 2 covered with the sealing resin 7. The first inner portion 22 extends inward from the first outer portion 21 into the sealing resin 7. In plan view, a first boundary 29 between the first inner portion 22 and the first outer portion 21 overlaps with a peripheral edge 79 of the sealing resin 7. In plan view, the first inner portion 22, except at its first boundary 29, is located inside the peripheral edge 79 of the sealing resin 7.

In one example, the first lead 2 of the present embodiment has the following dimensions. First, the dimension W21 of the first outer portion 21 in the second direction x (see FIG. 1) ranges from 0.1 to 1.5 mm, for example. Second, the dimension (width) in the second direction x of the portion connecting the first outer portion 21 and the first inner portion 22 (the first boundary 29) ranges from 0.1 to 1.5 mm, for example. Third, the dimension (thickness) of the first lead 2 at the first boundary 29 in the thickness direction z ranges from 100 to 150 μm, for example.

The second lead 3 includes a second outer portion 31 and a second inner portion 32. The second outer portion 31 and the second inner portion 32 are connected to each other and integrally formed.

The second outer portion 31 is the portion of the second lead 3 that is exposed from the sealing resin 7. The second outer portion 31 protrudes from the sealing resin 7 to the first side in the first direction y. In plan view, the second outer portion 31 is rectangular elongated in the first direction y. In the present embodiment, the shape of the second outer portion 31 is congruent with the shape of the first outer portion 21 in plan view. In another embodiment, the respective shapes are not necessarily congruent. The second outer portion 31 is located on a first side in the second direction x with respect to the first outer portion 21. The first outer portion 21 and the second outer portion 31 are located next to each other in the second direction x and separated by a first gap d23 (see FIG. 6). The first gap d23 ranges from 5 to 10 mm, for example. When the potential difference between the first outer portion 21 and the first inner portion 22 is about 800 V, the first gap d23 of 4 mm or longer is preferable. As viewed in the second direction x, the second outer portion 31 is bent into a gull-wing profile. As viewed in the second direction x, the second outer portion 31 overlaps with the first outer portion 21. The second outer portion 31 includes a second mounting section 311, a second root section 312, and a second intermediate section 313.

The second mounting section 311 is a terminal end of the second outer portion 31. For mounting the electronic device A1 on an electric vehicle, for example, the second mounting section 311 is bonded to the circuit board of the electric vehicle. As shown in FIGS. 1 and 2, the second mounting section 311 is at the end of the second outer portion 31 away from the sealing resin 7 in the first direction y. The second mounting section 311 is located farther from the sealing resin 7 in the first direction y than the second root section 312 and the second intermediate section 313. In the thickness direction z, the second mounting section 311 is located below the second root section 312. In the thickness direction z, the second mounting section 311 is located at the same (or substantially the same) position as the first mounting section 211.

The second root section 312 is the starting end of the second outer portion 31. As shown in FIGS. 1 and 2, the second root section 312 is the end of the second outer portion 31 closer to the sealing resin 7 in the first direction y. In the first direction y, the second root section 312 is located closer to the sealing resin 7 than the second mounting section 311 and the second intermediate section 313. The second root section 312 is located above the second mounting section 311 in the thickness direction z, and protrudes from the middle portion of the sealing resin 7 in the thickness direction z.

The second intermediate section 313 connects the second mounting section 311 and the second root section 312. As viewed in the second direction x, the second intermediate section 313 is inclined relative to the second mounting section 311 and the second root section 312.

The second inner portion 32 is the portion of the second lead 3 covered with the sealing resin 7. The second inner portion 32 is connected to the second outer portion 31. The second inner portion 32 extends inward from the second outer portion 31 into the sealing resin 7. In plan view, a second boundary 39 between the second inner portion 32 and the second outer portion 31 overlaps with the peripheral edge 79 of the sealing resin 7. In plan view, the second inner portion 32, except at its second boundary 39, is located inside the peripheral edge 79 of the sealing resin 7.

In one example, the second lead 3 of the present embodiment has the following dimensions. First, the dimension W31 of the second outer portion 31 in the second direction x (see FIG. 1) ranges from 0.1 to 1.5 mm, for example. In the present embodiment, the dimension W31 of the second outer portion 31 is equal to the dimension W21 of the first outer portion 21. In a different example, the dimension W21 and the dimension W31 may not be equal to each other. Second, the dimension (width) in the second direction x of the portion connecting the second outer portion 31 and the second inner portion 32 (the second boundary 39) ranges from 0.1 to 1.5 mm, for example. Third, the dimension (thickness) of the second lead 3 at the second boundary 39 in the thickness direction z ranges from 100 to 150 μm, for example.

Each third lead 4 includes a third outer portion 41 and a third inner portion 42. The third outer portion 41 and the third inner portion 42 of each third lead 4 are connected and integrally formed. Unless otherwise specifically noted, the description of the third outer portion 41 and the third inner portion 42 given below is common for all the third leads 4.

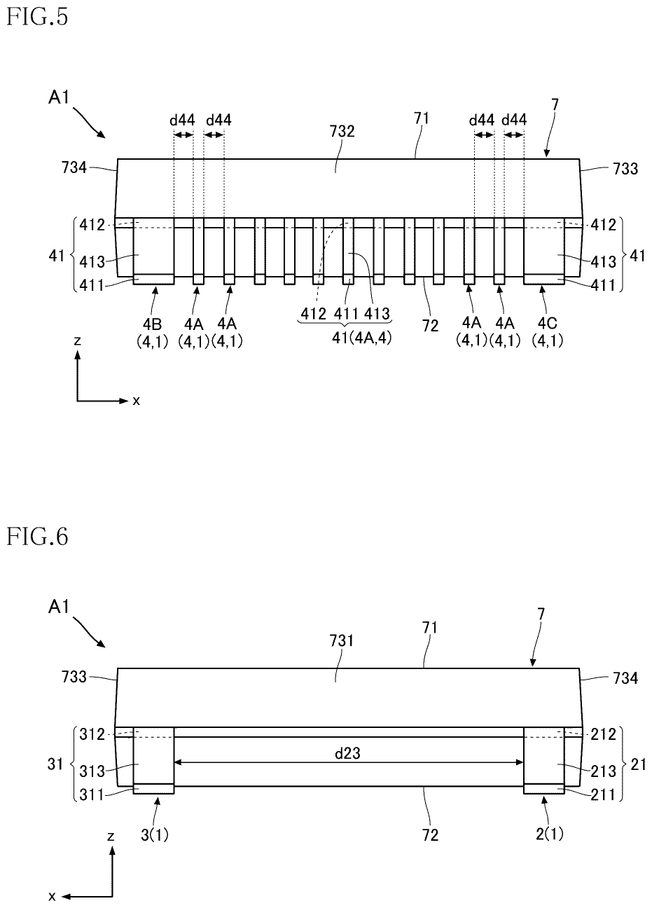

The third outer portion 41 is exposed from the sealing resin 7. The third outer portion 41 protrudes from the sealing resin 7 to a second side in the first direction y. In plan view, the third outer portion 41 is rectangular elongated in the first direction y. The third outer portions 41 are arranged at equal intervals in the second direction x. The third outer portions 41 are adjacent in the second direction x and parallel to each other. Each two adjacent third outer portions 41 in the second direction x are separated by a second gap d44 (see FIG. 5) in the second direction x. The second gap d44 is smaller than the first gap d23 and ranges from 0.25 to 5 mm, for example. As viewed in the second direction x, the third outer portion 41 is bent into a gull-wing profile. As viewed in the second direction x, the third outer portions 41 overlap with each other. The third outer portion 41 includes a third mounting section 411, a third root section 412, and a third intermediate section 413. Unless otherwise specifically noted, the description of the third mounting section 411, the third root section 412, and the third intermediate section 413 given below is common for all the third outer portions 41.

The third mounting section 411 is a terminal end of the third outer portion 41. For mounting the electronic device A1 on an electric vehicle, for example, the third mounting section 411 is bonded to the circuit board of the electric vehicle. As shown in FIGS. 1 and 2, the third mounting section 411 is the end of the third outer portion 41 away from the sealing resin 7 in the first direction y. The third mounting section 411 is located farther from the sealing resin 7 in the first direction y than the third root section 412 and the third intermediate section 413. The third mounting section 411 is located below the third root section 412 in the thickness direction z. In the thickness direction z, the respective third mounting sections 411 are located at the same (or substantially the same) position.

The third root section 412 is the starting end of the third outer portion 41. As shown in FIGS. 1 and 2, the third root section 412 is the end of the third outer portion 41 closer to the sealing resin 7 in the first direction y. The third root section 412 is located closer to the sealing resin 7 in the first direction y than the third mounting section 411 and the third intermediate section 413. The third root section 412 is located above the third mounting section 411 in the thickness direction z, and protrudes from the middle portion of the sealing resin 7 in the thickness direction z. In the thickness direction z, the respective third root sections 412 are located at the same (or substantially the same) position.

The third intermediate section 413 connects the third mounting section 411 and the third root section 412. As viewed in the second direction x, the third intermediate section 413 is inclined relative to the third mounting section 411 and the third root section 412.

The third inner portion 42 is covered with the sealing resin 7. The third inner portion 42 is connected to the third outer portion 41. The third inner portion 42 extends inward from the third outer portion 41 into the sealing resin 7. In plan view, a boundary 49 between the third inner portion 42 and the third outer portion 41 overlaps with the peripheral edge 79 of the sealing resin 7. In plan view, the third inner portion 42, except at its boundary 49, is located inside the peripheral edge 79 of the sealing resin 7.

The plurality of third leads 4 include a plurality of inner leads 4A and a pair of outer leads 4B and 4C. Each of the inner and outer leads 4A, 4B, and 4C includes a third outer portion 41 and a third inner portion 42.

The inner leads 4A are adjacent to each other in the second direction x. The pair of outer leads 4B and 4C are disposed on opposite sides of the plurality of inner leads 4A in the second direction x. Hence, the third outer portions 41 of the inner leads 4A are adjacent to each other in the second direction x, and the third outer portions 41 of the pair of outer leads 4B and 4C are located on opposite sides in the second direction x, with the third outer portions 41 of the inner leads 4A between them.

In one example, the third leads 4 of the present embodiment have the following dimensions. First, the dimension W41A of the third outer portion 41 of each inner lead 4A in the second direction x (see FIG. 1) ranges from 0.15 to 0.5 mm, for example. In the present embodiment, the dimension W41A is smaller than both of the dimension W21 of the first outer portion 21 and the dimension W31 of the second outer portion 31. Second, the dimensions W41B and W41C of the third outer portions 41 of the pair of outer leads 4B and 4C in the second direction x (see FIG. 1) each range from 0.15 to 1.5 mm, for example. In the present embodiment, the dimensions W41B and W41C are equal (or substantially equal) to the dimensions W21 and W31 of the first outer portion 21 and the second outer portion 31. Third, the dimension (width) of each inner lead 4A at the portion connecting the third outer portion 41 and the third inner portion 42 (the boundary 49) in the second direction x ranges from 0.15 to 0.5 mm, for example. The width of each inner lead 4A at the boundary 49 is equal (or substantially equal) to the dimension W41A of the third outer portion 41 of each inner lead 4A. Fourth, the dimension (thickness) of each inner lead 4A at its boundary 49 in the thickness direction z ranges from 100 to 150 μm, for example. Fifth, the dimension (width) in the second direction x of each of the pair of outer leads 4B and 4C at the portion connecting the third outer portion 41 and the third inner portion 42 (the boundary 49) ranges from 0.15 to 1.5 mm, for example. The width of each of the outer leads 4B and 4C at its boundary 49 is equal to (or substantially equal to) the dimensions W41B and W41C of the third outer portions 41 of the outer leads 4B and 4C. Sixth, the dimension (thickness) of each of the outer leads 4B and 4C at its boundary 49 in the thickness direction z ranges from 100 to 150 μm, for example.

As shown in FIG. 2, among the plurality of leads 1, the first inner portion 22 of the first lead 2 includes a first island portion 223, and the third inner portion 42 of the outer lead 4B includes a second island portion 423. The first island portion 223 and the second island portion 423 support the electronic component 5. The first island portion 223 and the second island portion 423 are spaced apart from each other. The shapes of the first island portion 223 and the second island portion 423 in plan view are not particularly limited, and both of the first island portion 223 and the second island portion 423 are rectangular in the illustrated example. As shown in FIG. 2, the first island portion 223 and the second island portion 423 may be aligned in the first direction y, with the first island portion 223 on the first side in the first direction y relative to the second island portion 423.

The electronic component 5 is an active element for the electrical function of the electronic device A1. The function of the electronic component 5 is not specifically limited. In the present embodiment, the electronic component 5 detects a voltage. The electronic component 5 includes a first chip 51 and a second chip 52.

The first chip 51 is mounted on the first island portion 223. In the present embodiment, the first chip 51 outputs a first signal corresponding to the potential of the first lead 2 and a second signal corresponding to the potential of the second lead 3 to the second chip 52. The first chip 51 is provided with a plurality of electrodes 511, 512, and 513 on its upper surface in the thickness direction z. The size of the first chip 51 is not specifically limited. In one example, the first chip 51 has a width (dimension in the thickness direction z) ranging from 100 to 400 μm, a dimension in the second direction x ranging from 3 to 4 mm, and a dimension in the first direction y ranging from 1.5 to 2.0 mm.

The second chip 52 is mounted on the second island portion 423. In the present embodiment, the second chip 52 receives the first signal and the second signal from the first chip 51 and outputs a third signal corresponding to the potential difference between the first lead 2 and the second lead 3. In short, the second chip 52 outputs a detection signal (third signal) that indicates the voltage applied between the first lead 2 and the second lead 3. The second chip 52 is provided with a plurality of electrodes 521 and 522 on its upper surface in the thickness direction z. The size of the second chip 52 is not specifically limited. In one example, the second chip 52 has a width (dimension in the thickness direction z) ranging from 100 to 400 μm, a dimension in the second direction x ranging from 2 to 3 mm, and a dimension in the first direction y ranging from 1.0 to 2.0 mm.

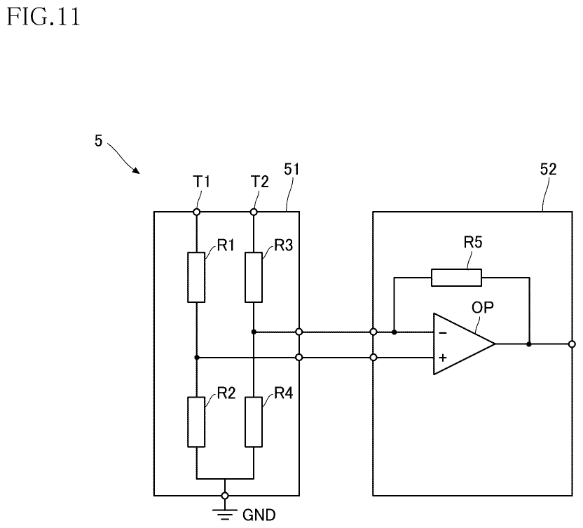

In the electronic device A1, the electronic component 5 (the first chip 51 and the second chip 52) form a circuit with the configuration shown in FIG. 11. As shown in FIG. 11, the first chip 51 includes a plurality of resistive elements R1 to R4, whereas the second chip 52 includes an operational amplifier OP and a resistive element R5. The circuit configuration shown in FIG. 11 is merely as an example, and the circuit configuration of the electronic component 5 is not limited to the one shown in FIG. 11.

The two resistive elements R1 and R2 are connected in series. The two resistive elements R1 and R2 divide the voltage at a terminal T1 (the potential difference between the potential at the terminal T1 and the reference potential of ground GND). In the present embodiment, the terminal T1 corresponds to each electrode 512. The junction of the two resistive elements R1 and R2 is connected to the non-inverting input terminal of the operational amplifier OP. The two resistive elements R3 and R4 are connected in series. The two resistive elements R3 and R4 divide the voltage at a terminal T2 (the potential difference between the potential at the terminal T2 and the reference ground potential GND). In the present embodiment, the terminal T2 corresponds to each electrode 511. The junction of the two resistive elements R3 and R4 is connected to the inverting input terminal of the operational amplifier OP. For the electronic device A1 to detect the voltage of a battery mounted on an electric vehicle, one of the terminals T1 and T2 is electrically connected to the high-voltage terminal of the battery, and the other to the low-voltage terminal of the battery.

The operational amplifier OP receives the first signal corresponding to the potential at the terminal T1 (in the present embodiment, the signal corresponding to a divided portion of the voltage at the terminal T1) and the second signal corresponding to the potential at the terminal T2 (in the present embodiment, the signal corresponding to a divided portion of the voltage at the terminal T2), and outputs the third signal corresponding to the potential difference between the terminals T1 and T2. The resistive element R5 is an element for determining the gain of the operational amplifier OP (feed resistor). The resistive element R5 has one end connected to the inverting input terminal of the operational amplifier OP and the other end connected to the output terminal of the operational amplifier OP. Note that the second chip 52 may or may not include a resistive element R5.

The wires 61 to 66 are used to electrically connect isolated components. The wires 61 to 66 are bonding wires. The material of the wires 61 to 66 contains Au, aluminum (Al), or Cu. The diameters of the wires 61 to 66 range, for example, from 20 to 40 μm for those containing Au, from 80 to 400 μm for those containing Al, and from 20 to 40 μm for those containing Cu. In the present embodiment, each of the wires 61 to 66 forms a loop in a triangular shape, but the loop shape may be trapezoidal instead.

As shown in FIG. 2, the wire 61 is bonded to an electrode 511 of the first chip 51 and the second inner portion 32, thereby electrically connecting the first chip 51 and the second lead 3. In other words, the second outer portion 31 of the second lead 3 is in electrical communication with the first chip 51 of the electronic component 5 through the second inner portion 32 and the wire 61.

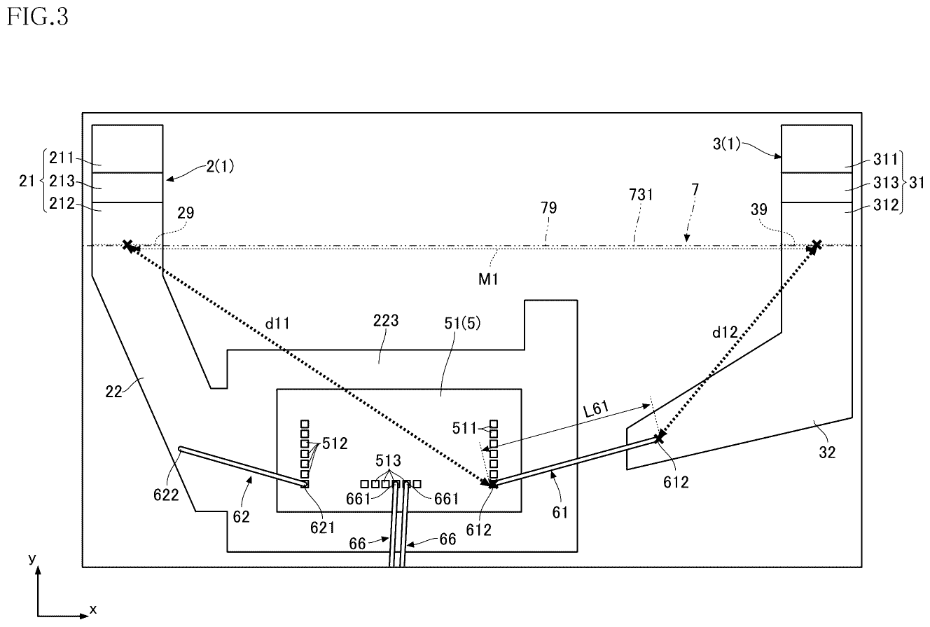

As shown in FIG. 3, the wire 61 includes a pair of bonding segments 611 and 612. The bonding segment 611 is bonded to the electrode 511. In the present embodiment, since the first chip 51 is bonded to the first island portion 223 (the first lead 2), the bonding segment 611 is secured to the first inner portion 22 of the first lead 2 via the first chip 51. The bonding segment 612 is bonded to the second inner portion 32.

The bonding segment 612 is directly secured to the second inner portion 32 of the second lead 3. Note that the wire 61 also includes a segment connecting the bonding segments 611 and 612.

As shown in FIG. 2, the wire 62 is bonded to an electrode 512 of the first chip 51 and the first inner portion 22, thereby electrically connecting the first chip 51 and the first lead 2. In other words, the first outer portion 21 of the first lead 2 is in electrical communication with the first chip 51 of the electronic component 5 through the first inner portion 22 and the wire 62.

As shown in FIG. 3, the wire 62 includes a pair of bonding segments 621 and 622. The bonding segment 621 is bonded to the electrode 512. In the present embodiment, since the first chip 51 is bonded to the first island portion 223 (the first lead 2), the bonding segment 621 is secured to the first inner portion 22 of the first lead 2 via the first chip 51. The bonding segment 622 is bonded to the first inner portion 22. The bonding segment 622 is directly secured to the first inner portion 22. Note that the wire 62 also includes a segment connecting the bonding segments 621 and 622.

As shown in FIG. 2, each wire 63 is bonded to an electrode 521 of the second chip 52 and the third inner portion 42 of an inner lead 4A, thereby electrically connecting the second chip 52 and the inner lead 4A. In other words, the third outer portion 41 of each inner lead 4A is in electrical communication with the second chip 52 of the electronic component 5 via the third inner portion 42 of the inner lead 4A and the wire 63.

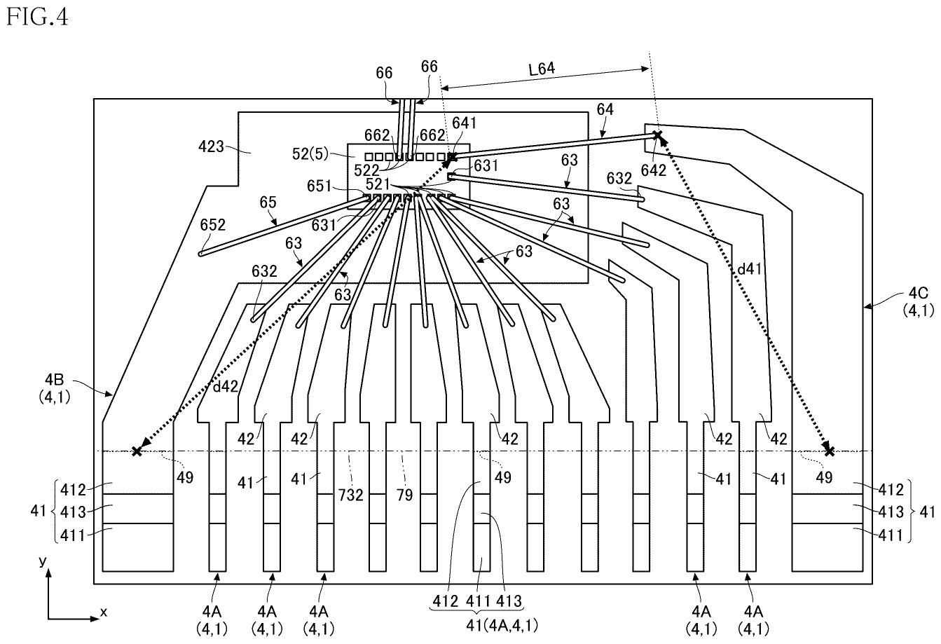

As shown in FIG. 4, each wire 63 includes a pair of bonding segments 631 and 632. The bonding segment 631 is bonded to the electrode 521. In the present embodiment, since the second chip 52 is bonded to the second island portion 423 (one of the outer leads 4B), the bonding segment 631 is secured to the third inner portion 42 of the outer lead 4B via the second chip 52. The bonding segment 632 is bonded to the third inner portion 42 of an inner lead 4A. The bonding segment 632 is directly secured to the third inner portion 42 of an inner lead 4A. Note that each wire 63 also includes a segment connecting the bonding segments 631 and 632.

As shown in FIG. 2, the wire 64 is bonded to an electrode 521 of the second chip 52 and the third inner portion 42 of an outer lead 4C, thereby electrically connecting the second chip 52 and the outer lead 4C. In other words, the third outer portion 41 of the outer lead 4C is in electrical communication with the second chip 52 of the electronic component 5 via the third inner portion 42 of the outer lead 4C and the wire 64.

As shown in FIG. 4, the wire 64 includes a pair of bonding segments 641 and 642. The bonding segment 641 is bonded to the electrode 521. In the present embodiment, since the second chip 52 is bonded to the second island portion 423 (the outer lead 4B), the bonding segment 641 is secured to the third inner portion 42 of the outer lead 4B via the second chip 52. The bonding segment 642 is bonded to the third inner portion 42 of the outer lead 4C. The bonding segment 642 is directly secured to the third inner portion 42 of the outer lead 4C. Note that the wire 64 also includes a segment connecting the bonding segments 641 and 642.

As shown in FIG. 2, the wire 65 is bonded to an electrode 521 of the second chip 52 and the third inner portion 42 of the outer lead 4B, thereby electrically connecting the second chip 52 and the outer lead 4B. In other words, the third outer portion 41 of the outer lead 4B is in electrical communication with the second chip 52 of the electronic component 5 via the third inner portion 42 of the outer lead 4B and the wire 65.

As shown in FIG. 4, the wire 65 includes a pair of bonding segments 651 and 652. The bonding segment 651 is bonded to the electrode 521. In the present embodiment, since the second chip 52 is bonded to the second island portion 423 (the outer lead 4B), the bonding segment 651 is secured to the third inner portion 42 of the outer lead 4B via the second chip 52. The bonding segment 652 is bonded to the third inner portion 42 of the outer lead 4B. The bonding segment 652 is directly secured to the third inner portion 42 of the outer lead 4B. Note that the wire 65 also includes a segment connecting the bonding segments 651 and 652.

As shown in FIG. 2, each wire 66 is bonded to an electrode 513 of the first chip 51 and an electrode 522 of the second chip 52, thereby electrically connecting the first chip 51 and the second chip 52.

As shown in FIGS. 3 and 4, each wire 66 includes a pair of bonding segments 661 and 662. The bonding segment 661 is bonded to the electrode 513. In the present embodiment, since the first chip 51 is bonded to the first island portion 223 (the first lead 2), the bonding segment 661 is secured to the first inner portion 22 of the first lead 2 via the first chip 51. The bonding segment 662 is bonded to the electrode 522. In the present embodiment, since the second chip 52 is bonded to the second island portion 423 (the outer lead 4B), the bonding segment 662 is secured to the third inner portion 42 of the outer lead 4B via the second chip 52. Note that each wire 66 also includes a segment connecting the bonding segments 661 and 662.

In the present embodiment, the wire 61 in plan view has a length that satisfies the following length conditions. That is, the length of the wire 61 in plan view is at least 25% and at most 65% of the average of a distance d11 and a distance d12, where d11 represents the distance from the bonding segment 611 to the first boundary 29 of the first lead 2, to which the bonding segment 611 is secured, and d12 represents the distance from the bonding segment 612 to the second boundary 39 of the second lead 3, to which the bonding segment 612 is secured. Specifically, in the present embodiment, the bonding segment 611 of the wire 61 is located at the distance d11 away from the first boundary 29 in plan view as shown in FIG. 3. The distance d11 is the length of a line segment connecting the midpoint of the first boundary 29 in the second direction x in plan view and the center of the bonding segment 611 in plan view (see FIG. 3). Additionally, in the present embodiment, the bonding segment 612 of the wire 61 is at the distance d12 away from the second boundary 39 in plan view as shown in FIG. 3. The distance d12 is the length of a line segment connecting the midpoint of the second boundary 39 in the second direction x in plan view and the center of the bonding segment 612 in plan view (see FIG. 3). In plan view, the wire 61 has a length L61 that is at least 25% and at most 65% of the average of the distances d11 and d12 ((d11+d12)/2) The wire 61 of the present embodiment is an example of the “first wire” recited in the claims. Similarly, the bonding segment 611 is an example of the “first bonding segment” recited in the claims, and the bonding segment 612 is an example of the “second bonding segment” in recited the claims. The distance d11 is an example of the “first distance” recited in the claims, and the distance d12 is an example of the “second distance” recited in the claims.

The lengths of the other wires 62 to 66 also satisfy the length conditions similar to those for the wire 61. That is, the length of the wire 62 in plan view is at least 25% and at most 65% of the average of the distance from the bonding segment 621 to the first boundary 29 of the first lead 2, to which the bonding segment 621 is secured, and the distance from the bonding segment 622 to the first boundary 29 of the first lead 2, to which the bonding segment 622 is secured. Similarly, the length of each wire 63 in plan view is at least 25% and at most 65% of the average of the distance from its bonding segment 631 to the boundary 49 of the outer lead 4B, to which the bonding segment 631 is secured, and the distance from its bonding segment 632 to the boundary 49 of the inner lead 4A, to which the bonding segment 632 is secured. The length of the wire 64 in plan view is at least 25% and at most 65% of the average of the distance from the bonding segment 641 to the boundary 49 of the outer lead 4B, to which the bonding segment 641 is secured, and the distance from the bonding segment 642 to the boundary 49 of the outer lead 4C, to which the bonding segment 642 is secured. Similarly, the length of the wire 65 in plan view is at least 25% and at most 65% of the average of the distance from the bonding segment 651 to the boundary 49 of the outer lead 4B, to which the bonding segment 651 is secured, and the distance from the bonding segment 652 to the boundary 49 of the outer lead 4B, to which the bonding segment 652 is secured. The length of each wire 66 in plan view is at least 25% and at most 65% of the average of the distance from its bonding segment 661 to the first boundary 29 of the first lead 2, to which the bonding segment 661 is secured, and the distance from its bonding segment 662 to the boundary 49 of the outer lead 4B, to which the bonding segment 662 is secured. Each of the wires 62 to 66 of the present embodiment is an example of the “second wire” recited in the claims.

In the present embodiment, the wire 64 is disposed such that the bonding segment 641 is at a distance d41 away from the boundary 49 of the outer lead 4B in plan view as shown in FIG. 4. The distance d41 is the length of a line segment connecting the midpoint of the boundary 49 of the outer lead 4B in the second direction x in plan view and the center of the bonding segment 641 in plan view (see FIG. 4). Additionally, the bonding segment 642 of the wire 64 is at a distance d42 away from the boundary 49 of the outer lead 4C in plan view as shown in FIG. 4. The distance d42 is the length of a line segment connecting the midpoint of the boundary 49 of the outer lead 4C in the second direction x in plan view and the center of the bonding segment 642 in plan view (see FIG. 4). The wire 64 has a length L64 that is at least 25% and at most 65% of the average of the distances d41 and d42 ((d41+d42)/2) in plan view.

The sealing resin 7 partly covers the plurality of leads 1 (the first lead 2, the second lead 3, the third leads 4, and fully covers the electronic component 5 (the first chip 51 and the second chip 52) and the wires 61 to 66. The material of the sealing resin 7 includes an insulating material, such as an epoxy resin. Preferably, the sealing resin 7 is made of a resin material with a Comparative Tracking Index (CTI) of 600 V or higher. The sealing resin 7 has the shape of a rectangular parallelepiped. For example, the sealing resin 7 measures from 5 to 15 mm in the second direction x and from 3 to 13 mm in the first direction y. The sealing resin 7 has a resin obverse surface 71, a resin reverse surface 72, a first resin side surface 731, a second resin side surface 732, a third resin side surface 733, and a fourth resin side surface 734.

The resin obverse surface 71 and the resin reverse surface 72 are spaced apart from each other in the thickness direction z. The resin obverse surface 71 faces the first side in the thickness direction z and the resin reverse surface 72 faces the second side in the thickness direction z. The resin obverse surface 71 is the upper surface of the sealing resin 7, and the resin reverse surface 72 is the lower surface of the sealing resin 7.

The first resin side surface 731 and the second resin side surface 732 are spaced apart from each other in the first direction y. The first resin side surface 731 faces the first side in the first direction y, and the second resin side surface 732 faces the second side in the first direction y. The third resin side surface 733 and the fourth resin side surface 734 are spaced apart from each other in the second direction x. The third resin side surface 733 faces the first side in the second direction x, and the fourth resin side surface 734 faces a second side in the second direction x.

As shown in FIGS. 1 to 3 and 6 to 8, the first outer portion 21 and the second outer portion 31 protrude from the first resin side surface 731. In plan view, the first lead 2 and the second lead 3 cross the first resin side surface 731. In plan view, the first boundary 29 and the second boundary 39 overlap with the first resin side surface 731. As shown in FIGS. 1, 2, 4, 5, 7 and 8, the plurality of third outer portions 41 protrude from the second resin side surface 732. In plan view, each third lead 4 crosses the second resin side surface 732. In plan view, the respective boundaries 49 overlap with the second resin side surface 732.

The electronic device A1 has the operation and effect as follows.

The electronic device A1 includes the first lead 2, the second lead 3, and the wire 61. The wire 61 includes the bonding segment 611 secured to the first inner portion 22 of the first lead 2, and the bonding segment 612 secured to the second inner portion 32 of the second lead 3. In plan view, the length of the wire 61 is at least 25% of the average of the distance d11 from the first boundary 29 to the bonding segment 611 and the distance d12 from the second boundary 39 to the bonding segment 612. The first boundary 29 is a dividing line between the first outer portion 21 and the first inner portion 22 in plan view, whereas the second boundary 39 is a dividing line between the second outer portion 31 and the second inner portion 32 in plan view. In the electronic device A1, the first inner portion 22, except at the first boundary 29 with the first outer portion 21, is located inside the peripheral edge 79 of the sealing resin 7. Also, the second inner portion 32, except at the second boundary 39 with the second outer portion 31, is located inside the peripheral edge 79 of the sealing resin 7. In the manufacturing phase of the electronic device A1, the plurality of leads 1 initially are a single lead frame. In this state, the first lead 2 and the second lead 3 are connected together via a tie bar. The first lead 2 and the second lead 3 are supported at one point by the tie bar. The first lead 2 and the second lead 3 of this configuration are susceptible to deformation during the manufacture of the electronic device A1 (e.g., during transfer between manufacturing steps of the electronic device A1). This may result in deformation or breakage of the wire 61. To address such deformation or breakage of the wire 61, study by the present inventor shows that the wire 61 is less susceptible to deformation or breakage when its length is at least 25% of the average of the distances d11 and d12. The electronic device A1 is configured such that the length of the wire 61 is at least 25% of the average of the distances d11 and d12. The electronic device A1 can therefore prevent deformation or breakage of the wire 61.

The electronic device A1 is configured such that the length of the wire 61 is at most 65% of the average of the distances d11 and d12. This configuration is effective in avoiding enlargement of the electronic device A1 (the sealing resin 7). Thus, the configuration of the electronic device A1 such that the length of the wire 61 in plan view is at least 25% and at most 65% of the average of the distances d11 and d12 is effective in preventing deformation or breakage of the wire 61 while avoiding enlargement of the electronic device A1 (the sealing resin 7).

In the electronic device A1, the first lead 2 includes the first island portion 223 on which the first chip 51 (the electronic component 5) is mounted. The first island portion 223 needs to have a sufficient area in plan view for the first chip 51 to be mounted. However, among the plurality of leads 1, the first lead 2 having a relatively large area in plan view is more susceptible to deformation during the manufacture of the electronic device A1. In other words, the wire 61 is more susceptible to deformation or breakage. Thus, setting the length of the wire 61 in plan view to be equal to or greater than the lower limit of the length conditions described above (equal to or greater than 25% of the average of the distances d11 and d12) is preferable for the reliability of the electronic device A1.

In the electronic device A1, each of the wires 61 to 66 forms a triangular loop. Study by the present inventor shows that a wire is generally more susceptible to deformation or breakage when in a triangular loop than in a trapezoidal loop. In the configuration in which each of the wires 61 to 66 forms a triangular loop, setting the lengths of the wires 61 to 66 in plan view to be equal to or greater than the lower limit of the length condition described above (to be equal to or greater than 25% of the average of the distances d11 and d12 in the case of the wire 68) is preferable for the reliability of the electronic device A1.

The first embodiment shows an example in which all of the wires 61 to 66 are configured to satisfy the length conditions described above. In a different example, the length conditions described above may be applied to one or more wires that are highly susceptible to deformation or breakage. When, for example, the wire 61 is highly susceptible to deformation or breakage, the length conditions for the wire 61 are applied only to the wire 61. In addition, when the wire 64 is also highly susceptible to deformation or breakage, the length conditions for the wire 64 are also applied to the wire 64. Which of the wires 61 to 66 is highly susceptible to deformation or breakage may be determined based on actual data obtained from the manufacture of the electronic device A1. Alternatively, the determination may be made based on verification data obtained from simulations during the design phase of the electronic device A1. Study by the present inventor shows that the wire 61 is likely to deform or break if the greater one of the distances d11 and d12 is 55% or more of a line segment Ml (see FIG. 3) connecting the first boundary 29 of the first lead 2, to which the bonding segment 611 is secured, and the second boundary 39 of the second lead 3, to which the bonding segment 612 is secured. In view of this, when the greater one of the distance d11 and d12 is 55% or more of the line segment Ml, the wire 61 is configured to have a length satisfying the length conditions described above. This holds true with respect to the other wires 62 to 66.

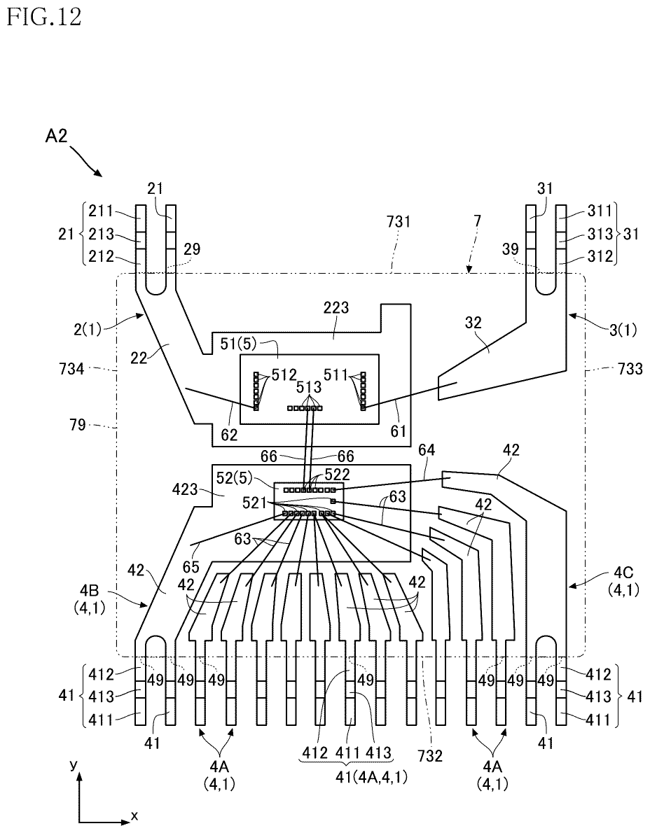

FIGS. 12 to 16 show an electronic device A2 according to a second embodiment. As shown in the figures, the electronic device A2 differs from the electronic device A1 in the following respect. That is, the configurations of the first lead 2, the second lead 3, and the pair of outer leads 4B and 4C are different.

As shown in FIGS. 12, 13 and 16, the first lead 2 of the electronic device A2 includes two separate first outer portions 21. In a different example, the first lead 2 may include three or more first outer portions 21. Each first outer portion 21 includes a first mounting section 211, a first root section 212, and a first intermediate section 213. As shown in FIG. 16, the two first outer portions 21 are adjacent to each other in the second direction x and separated by a gap d2. The gap d2 may or may not be equal to the second gap d44, for example.

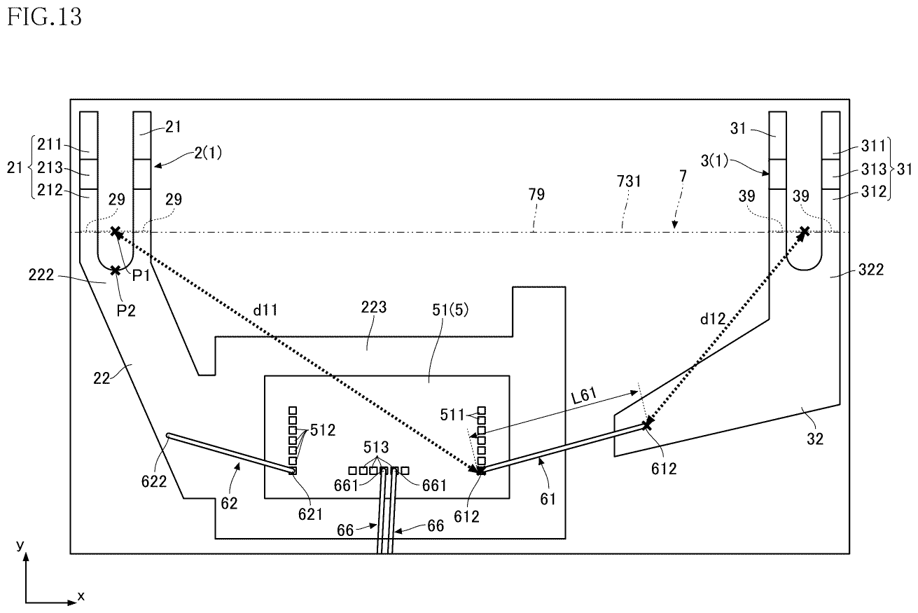

As shown in FIG. 13, the first lead 2 includes a first inner portion 22 having a first fork section 222. The first fork section 222 is located at the end of the first inner portion 22 that is connected to the two first outer portions 21. When the first lead 2 has two first outer portions 21, the first fork section 222 is divided into two prongs. The two prongs are connected at their ends to the first outer portions 21. Hence, the two first outer portions 21 are held at the same potential.

In the present embodiment, the first lead 2 includes the two first outer portions 21 and thus includes two first boundaries 29. Then, the distance d11 described above may be measured from a midpoint P1 between the two first boundaries 29 as shown in FIG. 13. In another example, the midpoint of one of the two first boundaries 29 (on the inside or the outside in the second direction x) may be used as the reference point for measuring the distance d11. In a yet another example, a root point of division P2 on the first fork section 222 (see FIG. 13) may be the reference point.

As shown in FIGS. 12, 13 and 16, the second lead 3 of the electronic device A2 includes two separate second outer portions 31. In a different example, the second lead 3 may include three or more second outer portions 31. Each second outer portion 31 includes a second mounting section 311, a second root section 312, and a second intermediate section 313. As shown in FIG. 16, the two second outer portions 31 are adjacent to each other in the second direction x and separated by a gap d3. The gap d3 may or may not be equal to the second gap d44, for example.

As shown in FIG. 13, the second lead 3 includes a second inner portion 32 having a second fork section 322. The second fork section 322 is located at the end of the second inner portion 32 that is connected to the two second outer portions 31. When the second lead 3 has two second outer portions 31, the second fork section 322 is divided into two prongs. The two prongs are connected at their ends to the second outer portions 31. Hence, the two second outer portions 31 are held at the same potential.

In the present embodiment, the second lead 3 includes the two second outer portions 31 and thus includes two second boundaries 39. Then, the distance d12 described above may be measured from a midpoint between the two second boundaries 39 as shown in FIG. 13. In another example, the midpoint of one of the two second boundaries 39 (on the inside or the outside in the second direction x) may be used as the reference point for measuring the distance d12. In a yet another example, a root point of division on the second fork section 322 may be the reference point.

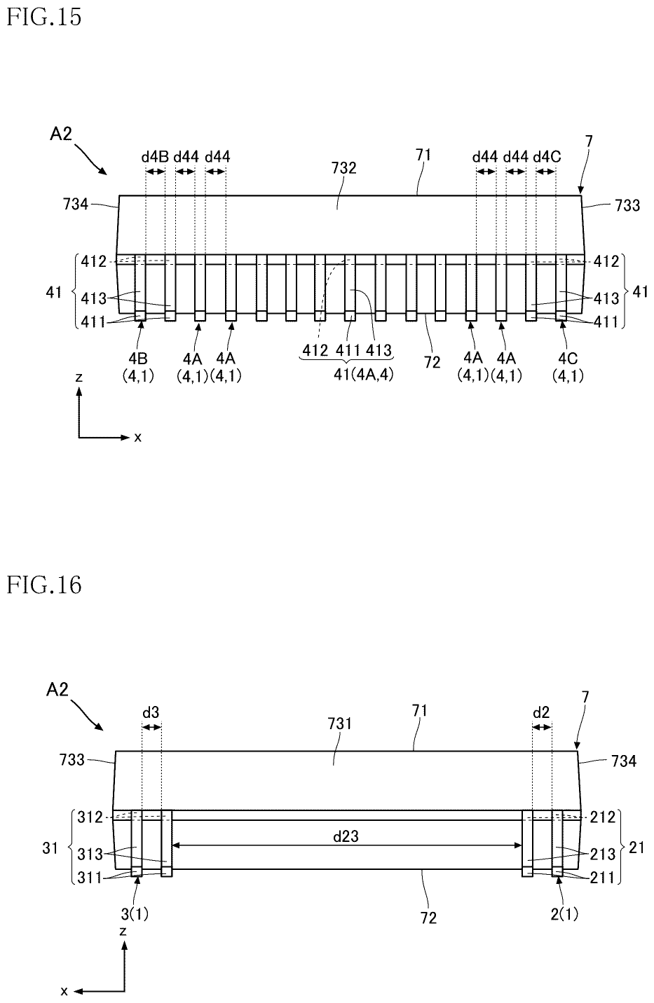

As shown in FIGS. 12, 14 and 15, each of the outer leads 4B and 4C of the electronic device A2 includes two separate third outer portions 41. In a different example, each of the outer leads 4B and 4C may include three or more third outer portions 41. Each of the two third outer portions 41 of the outer lead 4B or 4C includes a third mounting section 411, a third root section 412, and a third intermediate section 413. As shown in FIG. 15, the two second outer portions 31 of each of the outer leads 4B and 4C are adjacent to each other and separated by a gap d4B or d4C. The gaps d4B and d4C may or may not be equal to the second gap d44, for example.

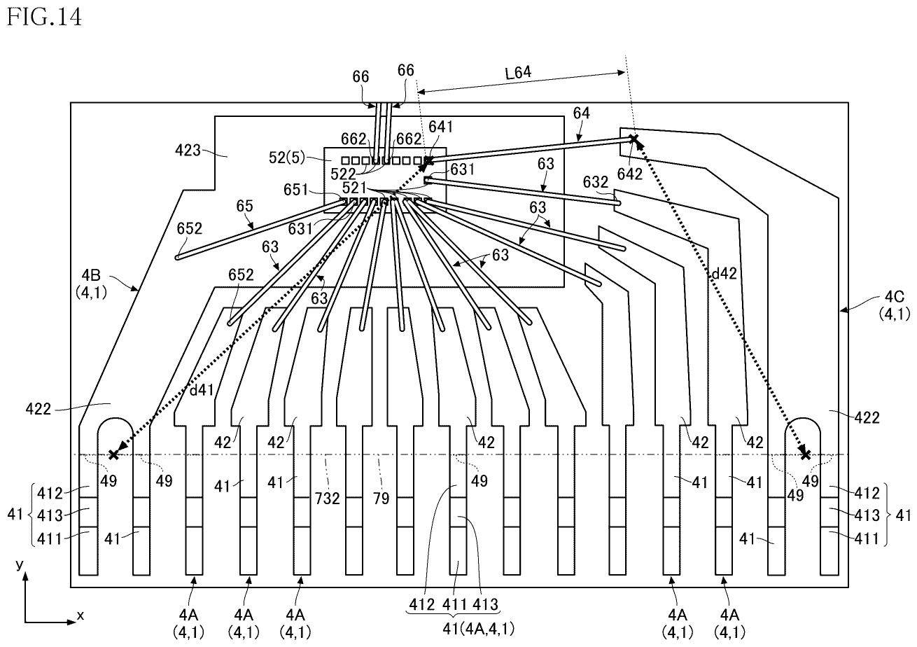

As shown in FIG. 14, each of the outer leads 4B and 4C includes a third inner portion 42 having a third fork section 422. Unless otherwise specifically noted, the description of the third fork section 422 given below is common for both of the outer leads 4B and 4C. The third fork section 422 is located at the end of the third inner portion 42 that is connected to the two third outer portions 41. When each of the outer leads 4B and 4C has two third outer portions 41, the third fork section 422 is divided into two prongs. The two prongs are connected at their ends to the third outer portions 41. Hence, the two third outer portions 41 of each of the outer leads 4B and 4C are held at the same potential.

In the present embodiment, each of the outer leads 4B and 4C includes the two third outer portions 41 and thus includes two boundaries 49. Then, the distance d41 or d42 described above may be measured from a midpoint between the two boundaries 49 as shown in FIG. 14. In another example, the midpoint of one of the two boundaries 49 (on the inside or the outside in the second direction x) may be used as the reference point for measuring the distance d41 or d42. In a yet another example, a root point of division on the third fork section 422 may be the reference point.

Similarly to the electronic device A1, the electronic device A2 can prevent deformation or breakage of the wire 61 by setting the length of the wire 61 in plan view to be equal to or greater than the lower limit of the length conditions described above (equal to or greater than 25% of the average of the distances d11 and d12). In addition, setting the length of the wire 61 in plan view to be equal to or less than the upper limit of the length conditions described above (equal to or less than 65% of the average of the distances d11 and d12) is preferable for avoiding enlargement of the electronic device A2. These hold true with respect to the other wires 62 to 66. Additionally, the electronic device A2 has a configuration in common with the electronic device A1, thereby achieving the same effect as the electronic device A1.

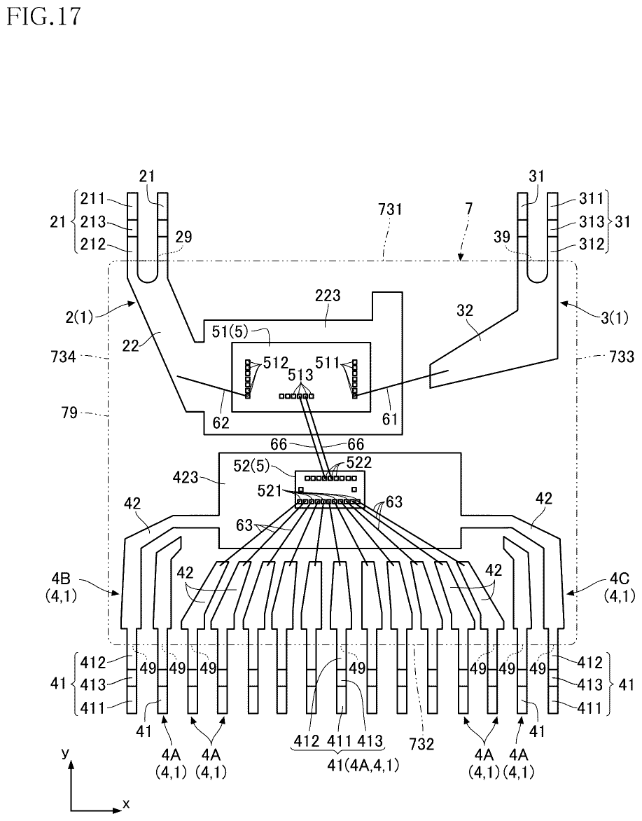

The second embodiment shows an example in which each of the outer leads 4B and 4C has two third outer portions 41. In a different example, each of the outer leads 4B and 4C has one third outer portion 41. FIG. 17 shows such an electronic device as a variation of the second embodiment. In the electronic device shown in FIG. 17, the third outer portion 41 of each of the outer leads 4B and 4C has a width (a dimension in the second direction x) equal to (or substantially equal to) the width (the dimension in the second direction x) of the third outer portion 41 of each inner lead 4A. In the electronic device shown in FIG. 17, the outer lead 4C is connected to the second island portion 423 of the outer lead 4B, so that the outer leads 4B and 4C are formed as one piece. The electronic device shown in FIG. 17 achieves the same effect as the electronic device A2. For the electronic device shown in FIG. 17, the outer leads 4B and 4C are formed as one piece. Thus, in the manufacturing phase of the electronic device shown in FIG. 17, the outer leads 4B and 4C are supported at two points by tie bars. Consequently, the outer leads 4B and 4C are less susceptible to deformation. Thus, wires to be attached to the outer leads 4B and 4C are not required to meet the length conditions described above. However, to avoid lowering of the reliability due to wire deformation and breakage, it is preferable to apply the length conditions described above also to the wires to be attached to the outer leads 4B and 4C.

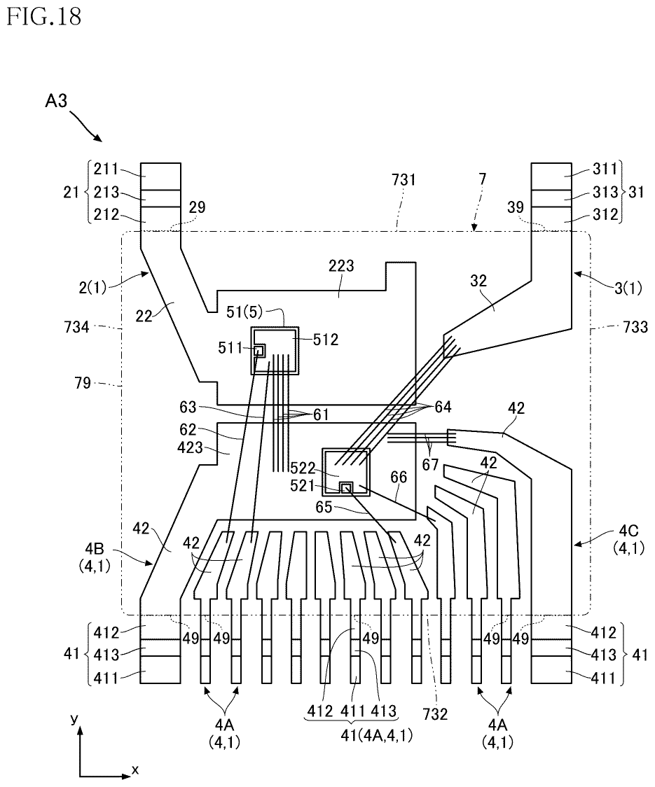

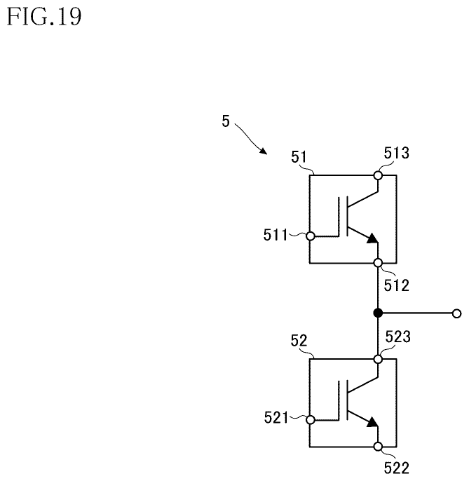

FIGS. 18 and 19 show an electronic device A3 according to a third embodiment. As shown in the figures, the electronic device A3 differs from the electronic device A1 in the function of the electronic component 5.

The electronic component 5 of the electronic device A3 has a power conversion function instead of the voltage detection function. In the present embodiment, the first chip 51 and the second chip 52 are switching elements. FIG. 19 shows a circuit diagram of an example in which the first chip 51 and the second chip 52 are insulated gate bipolar transistors (IGBTs). In another example, the first chip 51 and the second chip 52 may be other types of transistors, such as bipolar transistors.

As shown in FIG. 19, the first chip 51 includes three electrodes 511, 512, and 513. In the example in which the first chip 51 is an IGBT, the electrode 511 is the gate, the electrode 512 is the emitter, and the electrode 513 is the collector. For example, the first chip 51 has a vertical structure, with the electrodes 511 and 512 disposed on the upper surface (the surface facing upward in the thickness direction z) and the electrode 513 on the lower surface (the surface facing downward in the thickness direction z). As shown in FIG. 18, the first chip 51 is bonded to the first island portion 223 with a conductive bonding material (not shown), such as solder. The electrode 513 on the lower surface of the first chip 51 is electrically connected to the first island portion 223 through the conductive bonding material.

As shown in FIG. 19, the second chip 52 includes three electrodes 521, 522, and 523. In the example in which the second chip 52 is an IGBT, the electrode 521 is the gate, the electrode 522 is the emitter, and the electrode 523 is the collector. For example, the second chip 52 has a vertical structure, with the electrodes 521 and 522 disposed on the upper surface (the surface facing upward in the thickness direction z) and the electrode 523 on the lower surface (the surface facing downward in the thickness direction z). As shown in FIG. 18, the second chip 52 is bonded to the second island portion 423 with a conductive bonding material (not shown), such as solder. The electrode 523 on the lower surface of the second chip 52 is electrically connected to the second island portion 423 through the conductive bonding material.

The first chip 51 and the second chip 52 may have a horizontal structure instead of a vertical structure. In the horizontal structure, the electrode 513 is disposed on the upper surface of the first chip 51, and the electrode 523 is disposed on the upper surface of the second chip 52. Then, the electrode 513 is electrically connected to the first inner portion 22 with a bonding wire or a metal plate, whereas the electrode 523 is electrically connected to the third inner portion 42 of the outer lead 4B with a bonding wire or a metal plate.

In the electronic device A3, a plurality of wires 61 are bonded at one end to the electrode 512 and at the other end to the second island portion 423, thereby electrically connecting the electrode 512 and the second island portion 423. That is, the outer lead 4B is in electrical communication with the electrode 512 via the wires 61.

The wire 62 is bonded at one end to the electrode 511 and at the other end to the third inner portion 42 of an inner lead 4A, thereby electrically connecting the electrode 511 and the inner lead 4A. The third outer portion 41 of the inner lead 4A to which the wire 62 is bonded serves as an input terminal for a drive signal that drives the first chip 51.

The wire 63 is bonded at one end to the electrode 512 and at the other end to the third inner portion 42 of an inner lead 4A, thereby electrically connecting the electrode 512 and the inner lead 4A. The third outer portion 41 of the inner lead 4A to which the wire 63 is bonded serves as a sensing terminal for detecting the current flowing through the first chip 51 (the emitter current in the electronic device A3).

Each wire 64 is bonded at one end to the electrode 522 and at the other end to the second inner portion 32 of the second lead 3, thereby electrically connecting the electrode 522 and the second lead 3. That is, the second lead 3 is in electrical communication with the electrode 522 via the wires 64.

The wire 65 is bonded at one end to the electrode 521 and at the other end to the third inner portion 42 of an inner lead 4A, thereby electrically connecting the electrode 521 and the third inner portion 42. The third outer portion 41 of the inner lead 4A to which the wire 65 is bonded serves as an input terminal for a drive signal that drives the second chip 52.

The wire 66 is bonded at one end to the electrode 522 and at the other end to the third inner portion 42 of an inner lead 4A, thereby electrically connecting the electrode 522 and the inner lead 4A. The third outer portion 41 of the inner lead 4A to which the wire 66 is bonded serves as a sensing terminal for detecting the current flowing through the second chip 52 (the emitter current in the electronic device A3). Note that each of the wires 62, 63, 65 and 66 is connected to a different one of the inner leads 4A.

The wires 67 are bonded at one end to the second island portion 423 and at the other end to the third inner portion 42 of the outer lead 4C, thereby electrically connecting the second island portion 423 and the outer lead 4C. That is, the outer lead 4C is in electrical communication with the outer lead 4B via the wires 67. In the electronic device A3, the outer lead 4B is electrically connected to the electrode 523, so that the outer lead 4C is electrically connected to the electrode 523.

In the electronic device A3, the power supply voltage (e.g., DC voltage) is applied between the first outer portion 21 and the first inner portion 22. This voltage is converted into a predetermined voltage (e.g., AC voltage) through switching operations of the first chip 51 and the second chip 52. The resulting voltage is output from the third outer portions 41 of the outer leads 4B and 4C.

Similarly to the electronic devices A1 and A2, the electronic device A3 can prevent deformation or breakage of the wires 61 by setting the length of each wire 61 in plan view to be equal to or greater than the lower limit of the length conditions described above (equal to or greater than 25% of the average of the distances d11 and d12). In addition, setting the length of each wire 61 in plan view to be equal to or less than the upper limit of the length conditions described above (equal to or less than 65% of the average of the distances d11 and d12) is preferable for avoiding enlargement of the electronic device A3. These hold true with respect to the other wires 62 to 67. Additionally, the electronic device A3 has a configuration in common with the electronic devices A1 and A2, thereby achieving the same effect as the electronic devices A1 and A2.

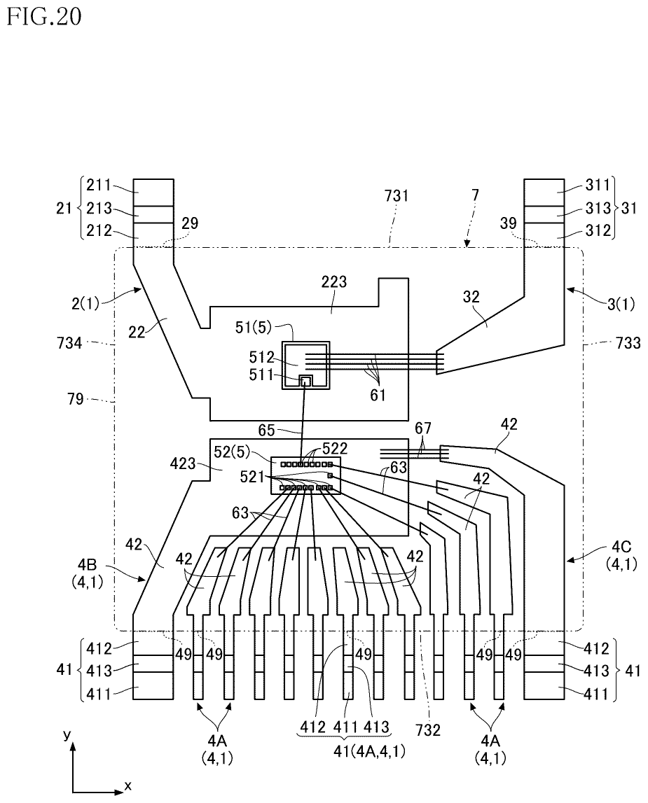

The third embodiment shows an example in which both of the first chip 51 and the second chip 52 are switching elements. In a different example, the second chip 52 may be a control IC that controls operation of the first chip 51, rather than a switching element. FIG. 20 shows such an electronic device as a variation of the third embodiment. In the electronic device shown in FIG. 20, the second chip 52 outputs a drive signal to the first chip 51 via the wire 65. In the electronic device shown in FIG. 20, the wires 61 are bonded at one end to the electrode 512 and at the other end to the second inner portion 32. The electronic device shown in FIG. 20 achieves the same effect as the electronic device A3.

As is clear from the third embodiment and its variation, the function of the electronic component 5 of the electronic device according to the present disclosure is not limited to voltage detection. In addition, in the electronic device according to the present disclosure, the electronic component 5 (the first chip 51 and the second chip 52) includes a semiconductor element that is made of a semiconductor material. In other words, the electronic device according to the present disclosure may be a semiconductor device that includes a semiconductor element as the electronic component 5. As is clear from the third embodiment, the length conditions may be applied to any wires and not limited to a wire bonded to a lead 1 and the electronic component 5, a wire bonded to different portions of the electronic component 5 (the first chip 51 and the second chip 52), and a wire bonded to different leads 1.

The electronic device according to the present disclosure is not limited to the embodiments described above. Various design changes may be made freely in the specific structure of each part of the electronic device according to the present disclosure. For example, the present disclosure includes electronic devices according to the following clauses.

Clause 1. An electronic device comprising:
an electronic component;
a sealing resin covering the electronic component;
a first lead including a first inner portion covered with the sealing resin and a first outer portion exposed from the sealing resin;
a second lead including a second inner portion covered with the sealing resin and a second outer portion exposed from the sealing resin; and
a first wire including a first bonding segment secured to the first inner portion and a second bonding segment secured to the second inner portion,
wherein the first inner portion is connected to the first outer portion and is located inside a peripheral edge of the sealing resin as viewed in a thickness direction of the sealing resin, except at a first boundary with the first outer portion,
the second inner portion is connected to the second outer portion and is located inside the peripheral edge of the sealing resin as viewed in the thickness direction, except at a second boundary with the second outer portion,
the first bonding segment is a first distance away from the first boundary as viewed in the thickness direction,
the second bonding segment is a second distance away from the second boundary as viewed in the thickness direction, and
as viewed in the thickness direction, a length of the first wire is at least 25% of an average of the first distance and the second distance.

Clause 2. The electronic device according to Clause 1, wherein as viewed in the thickness direction, the length of the first wire is at most 65% of the average of the first distance and the second distance.

Clause 3. The electronic device according to Clause 1 or 2, wherein the electronic component includes a first chip, the first inner portion includes a first island portion, and the first chip is mounted on the first island portion.

Clause 4. The electronic device according to Clause 3, wherein the first bonding segment is bonded to the first chip and secured to the first inner portion via the first chip.

Clause 5. The electronic device according to Clause 4, wherein the second bonding segment is bonded to the second inner portion.

Clause 6. The electronic device according to any one of Clauses 3 to 5, wherein the sealing resin includes a first resin side surface facing a first side in a first direction orthogonal to the thickness direction, and the first lead and the second lead cross the first resin side surface as viewed in thickness direction.

Clause 7. The electronic device according to Clause 6, wherein in plan view, a greater one of the first distance and the second distance is at least 55% of a length of a line segment connecting the first boundary and the second boundary.

Clause 8. The electronic device according to Clause 6 or 7, further comprising a plurality of third leads each including a third inner portion covered with the sealing resin and a third outer portion exposed from the sealing resin.

Clause 9. The electronic device according to Clause 8, wherein the sealing resin includes a second resin side surface facing a second side in the first direction, and the third leads cross the second resin side surface as viewed in thickness direction.

Clause 10. The electronic device according to Clause 9, wherein the first outer portion and the second outer portion are located next to each other and spaced apart by a first gap in a second direction orthogonal to the thickness direction and the first direction,
third terminal portions of the third leads are evenly spaced apart from each other by a second gap in the second direction, and
the first gap is greater than the second gap.

Clause 11. The electronic device according to Clause 10, wherein the plurality of third leads include at least one inner lead and a pair of outer leads at opposite sides of the at least one inner lead in the second direction.

Clause 12. The electronic device according to Clause 11, wherein the electronic component includes a second chip, one of the pair of the outer leads includes a second island portion, and the second chip is mounted on the second island portion.

Clause 13. The electronic device according to Clause 12, wherein the first chip includes a resistive element and is configured to output a first signal corresponding to a potential of the first outer portion and a second signal corresponding to a potential of the second outer portion, and
the second chip includes an operational amplifier and is configured to receives the first signal and the second signal and output a third signal corresponding to a potential difference between the first outer portion and the second outer portion.

Clause 14. The electronic device according to any one of Clauses 1 to 13, further comprising:
one or more second wires different from the first wire; and
a plurality of leads including the first lead and the second lead,
wherein each of the one or more second wires includes a third bonding segment bonded to one of the plurality of leads and a fourth bonding segment bonded to another one of the plurality of leads.

Clause 15. The electronic device according to Clause 14, wherein each of the plurality of leads includes an inner portion covered with the sealing resin and an outer portion exposed from the sealing resin,
as viewed in the thickness direction, the third bonding segment is a third distance away from a third boundary between the inner portion and the outer portion of the one lead to which the third bonding segment is secured,
as viewed in the thickness direction, the fourth bonding segment is a fourth distance away from a fourth boundary between the inner portion and the outer portion of the one lead to which the fourth bonding segment is secured, and
as viewed in the thickness direction, a length of each of the one or more second wires is at least 25% of an average of the third distance and the fourth distance.

Clause 16. The electronic device according to Clause 15, wherein as viewed in the thickness direction, the length of each of the one or more second wires is at most 65% of the average of the third distance and the fourth distance.

REFERENCE NUMERALS

| | |
|---|---|
| A1, A2, A3: electronic device | 1: lead |
| 2: first lead | 21: first outer portion |
| 211: first mounting section | 212: first root section |
| 213: first intermediate section | 22: first inner portion |
| 222: first fork section | 223: first island portion |
| 29: first boundary | 3: second lead |
| 31: second outer portion | 311: second mounting section |
| 312: second root section | 313: second intermediate section |
| 32: second inner portion | 322: second fork section |
| 39: second boundary | 4: third lead |
| 4A: inner lead | 4B, 4C: outer lead |
| 41: third outer portion | 411: third mounting section |
| 412: third root section | 413: third intermediate section |
| 42: third inner portion | 422: third fork section |
| 423: second island portion | 49: boundary |
| 5: electronic component | 51: first chip |
| 511, 512, 513: electrode | 52: second chip |
| 521, 522, 523: electrode | 61 to 67: wire |
| 611, 612: bonding segment | 621, 622: bonding segment |
| 631, 632: bonding segment | 641, 642: bonding segment |
| 651, 652: bonding segment | 661, 662: bonding segment |
| 7: sealing resin | 71: resin obverse surface |
| 72: resin reverse surface | 731: first resin side surface |
| 732: second resin side surface | 733: third resin side surface |
| 734: fourth resin side surface | 79: peripheral edge |
| GND: ground | OP: operational amplifier |
| R1 to R5: resistive element | T1, T2: terminal |

1. An electronic device comprising:
an electronic component;
a sealing resin covering the electronic component;
a first lead including a first inner portion covered with the sealing resin and a first outer portion exposed from the sealing resin;
a second lead including a second inner portion covered with the sealing resin and a second outer portion exposed from the sealing resin; and
a first wire including a first bonding segment secured to the first inner portion and a second bonding segment secured to the second inner portion,
wherein the first inner portion is connected to the first outer portion and is located inside a peripheral edge of the sealing resin as viewed in a thickness direction of the sealing resin, except at a first boundary with the first outer portion,
the second inner portion is connected to the second outer portion and is located inside the peripheral edge of the sealing resin as viewed in the thickness direction, except at a second boundary with the second outer portion,
the first bonding segment is a first distance away from the first boundary as viewed in the thickness direction,
the second bonding segment is a second distance away from the second boundary as viewed in the thickness direction, and
as viewed in the thickness direction, a length of the first wire is at least 25% of an average of the first distance and the second distance.

2. The electronic device according to claim 1, wherein as viewed in the thickness direction, the length of the first wire is at most 65% of the average of the first distance and the second distance.

3. The electronic device according to claim 1, wherein the electronic component includes a first chip,
the first inner portion includes a first island portion, and
the first chip is mounted on the first island portion.

4. The electronic device according to claim 3, wherein the first bonding segment is bonded to the first chip and secured to the first inner portion via the first chip.

5. The electronic device according to claim 4, wherein the second bonding segment is bonded to the second inner portion.

6. The electronic device according to claim 3, wherein the sealing resin includes a first resin side surface facing a first side in a first direction orthogonal to the thickness direction, and
the first lead and the second lead cross the first resin side surface as viewed in thickness direction.

7. The electronic device according to claim 6, wherein in plan view, a greater one of the first distance and the second distance is at least 55% of a length of a line segment connecting the first boundary and the second boundary.

8. The electronic device according to claim 6, further comprising a plurality of third leads each including a third inner portion covered with the sealing resin and a third outer portion exposed from the sealing resin.

9. The electronic device according to claim 8, wherein the sealing resin includes a second resin side surface facing a second side in the first direction, and
the third leads cross the second resin side surface as viewed in thickness direction.

10. The electronic device according to claim 9, wherein the first outer portion and the second outer portion are located next to each other and spaced apart by a first gap in a second direction orthogonal to the thickness direction and the first direction,
third terminal portions of the third leads are evenly spaced apart from each other by a second gap in the second direction, and
the first gap is greater than the second gap.

11. The electronic device according to claim 10, wherein the plurality of third leads include at least one inner lead and a pair of outer leads at opposite sides of the at least one inner lead in the second direction.

12. The electronic device according to claim 11, wherein the electronic component includes a second chip,
one of the pair of the outer leads includes a second island portion, and
the second chip is mounted on the second island portion.

13. The electronic device according to claim 12, wherein the first chip includes a resistive element and is configured to output a first signal corresponding to a potential of the first outer portion and a second signal corresponding to a potential of the second outer portion, and
the second chip includes an operational amplifier and is configured to receive the first signal and the second signal and output a third signal corresponding to a potential difference between the first outer portion and the second outer portion.

14. The electronic device according to claim 1, further comprising:
one or more second wires different from the first wire; and
a plurality of leads including the first lead and the second lead,
wherein each of the one or more second wires includes a third bonding segment bonded to one of the plurality of leads and a fourth bonding segment bonded to another one of the plurality of leads.

15. The electronic device according to claim 14, wherein each of the plurality of leads includes an inner portion covered with the sealing resin and an outer portion exposed from the sealing resin,
as viewed in the thickness direction, the third bonding segment is a third distance away from a third boundary between the inner portion and the outer portion of the one lead to which the third bonding segment is secured,
as viewed in the thickness direction, the fourth bonding segment is a fourth distance away from a fourth boundary between the inner portion and the outer portion of the one lead to which the fourth bonding segment is secured, and
as viewed in the thickness direction, a length of each of the one or more second wires is at least 25% of an average of the third distance and the fourth distance.

16. The electronic device according to claim 15, wherein as viewed in the thickness direction, the length of each of the one or more second wires is at most 65% of the average of the third distance and the fourth distance.
